(19) United States
(12) Patent Application Publication
(10) Pub. No.: US 2005/0280358 A1
(43) Pub. Date: Dec. 22, 2005

(54) Light-polarizing film with high permeability for improving an interference light of a color organic light emitting diode

(76) Inventors: Yaw-Chung Cheng, Taipei (TW); Chia-Lin Hsieh, Zhongli City (TW)

Correspondence Address: BIRCH STEWART KOLASCH & BIRCH, PO BOX 747, FALLS CHURCH, VA, 22040-0747, US

(21) Appl. No.: 10/868,786

(22) Filed: Jun. 17, 2004

(51) Int. Cl. H01J 1/62; H01J 63/04

(52) U.S. Cl. 313/504

(57) ABSTRACT

A light-polarizing film with high permeability for improving an interference light of a color organic light emitting diode (OLED), wherein a phase retardation plate is disposed on the color OLED for transforming light phase, and the light-polarizing film is disposed on the phase retardation plate for absorbing the projective light. The polarization degree of the light-polarizing film is between 15% and 93%, the corresponding permeability is between 46% and 80%, whereby the light-polarizing film with high permeability is utilizes to acquire necessary light-polarizing effect of emitting light of the color OLED itself, the color OLED doesn't need to increase power, and the color OLED can keep original economical lifetime. Furthermore, the incident external interference light is partly absorbed by the light-polarizing film; and the phase the incident external interference light is transformed by the phase retardation plate, the external interference light is reflected by the color OLED to be reflected light, the reflected light is transformed by the phase retardation plate again, and the reflected light is mostly absorbed by the light-polarizing film so as to improve the interference light.

### FIELD OF THE INVENTION

The present invention relates to a light-polarizing film with high permeability for improving an interference light of a color OLED, and more particularly to a light-polarizing film with high permeability absorbing and reflecting the interference light, whereby the necessary light-polarizing effect is acquired, the color OLED doesn't need to increase power, and the color OLED can keep original economical lifetime.

### BACKGROUND OF THE INVENTION

From conventional TV screen with cathode-ray tubes to current TFT panel display with high colorful density, not only the quality and quantity is increased in the high-tech filed, but also the next generation of display is further expected and requested in the market. Lately, many national well-known companies have changed their target and developed an Organic Light Emitting Diode (OLED) and Ploymer Light Emitting Diode (PLED) to apply in the next generation of panel display with high quality.

The structure and light emitting principle of the OLED are similar to those of a light emitting diode, the OLED has many advantages, such as self emitting light, little weight and size, simple structure, low driving voltage, wide visual angle, etc. The advantage of the self-emitting light is that the OLED can emit light by itself instead of a backlight module. The advantage of the little weight and size is that the weight of the OLED is not only light but also the thickness of the OLED is less than 1.5 mm. The advantage of the simple structure is that the cost of the OLED is low but also the lasting of the OLED is increased. The advantage of the low driving voltage is that the low operating voltage is less 10V, generally the low operating voltage is merely less 5V for driving the OLED so as to save power. The advantage of the wide visual angle is that the wide visual angle is more than 160 degrees upward, downward, leftward and rightward so as to be viewed. The OLED has an advantage of good illumination, high brightness, and high contrast so as to acquire good display quality. The OLED has an advantage that the fast response is less 10 μs or merely less than 1 μs so as to be conveniently used. The OLED utilizes a RGB fluorescent material or a color filter to achieve the object of full color so as to be widely applied. The OLED utilizes a plastic substrate to acquire the advantage of flexibility so as to realize a flexible display device. The temperature of the OLED can be within the wide range from −40 degrees centigrade to 60 degrees. centigrade.

The color OLED is a self-emitting light source. There is apparent reflective image on a panel after external light source emits light to a bottom aluminum plate, and therefore it is necessary to have a light-polarizing film (or plate) for filtering an incident light and separating the incident light into a part of one which pass through light-polarizing film and the other one which is masked by means of absorbing, reflecting and scattering. However, the permeability and polarization degree of conventional light-polarizing film is lower than those of current light-polarizing film such that the illumination and contrast of the OLED with conventional light-polarizing film is low. For example, Taiwan Patent No. 500931 discloses that a light-polarizing film has the permeability being more than 35% and the polarization degree being more than 90%. For example, Japanese Patent No. 59-159109 also discloses that a light-polarizing film has the permeability being more than 30%. The above-mentioned permeability is low and cause the illumination of the OLED is not enough. In order to increase the illumination and brightness, the power of the OLED must be increased. Oppositely, the lifetime of the OLED is decreased because the power of the OLED is increased. As shown in FIG. 9, it is a schematic diagram showing the relation between the illumination and lifetime of The OLED. If the illumination is controlled within 0.6 (600 cd/m2), then the illumination will not affect the economical lifetime of the OLED. However, if the illumination is increased above 1 (1000 cd/m2), then the illumination will be gradually decreased as time is increased and the economical lifetime at most is 2500 hours. In addition, U.S. Pat. Nos. 6,356,376 and 6,512,624 also disclose that a light-polarizing film is applied to a rearview mirror for decreasing the interference of external light source so as to show the light-polarizing film to widely apply to various field. However, there is no detailed research to be seen about a light-polarizing film being effectively applied to the OLED. There is no description about the light-polarizing film having functions of avoiding glisten and reflective light, neither. If the OLED needs functions of avoiding glisten and reflective light, then the OLED needs to be provided with an additional goggles.

Accordingly, there exists a need for a light-polarizing film with high permeability to solve the above-mentioned problems and disadvantages.

### SUMMARY OF THE INVENTION

It is an object of the present invention to provide a light-polarizing film with high permeability and a phase retardation plate to cause a color OLED to acquire high contrast and brightness.

In order to achieve the foregoing objects, the present invention provides a light-polarizing film with high permeability for improving an interference light of a color organic light emitting diode (OLED), wherein a phase retardation plate is disposed on the color OLED for transforming light phase, and the light-polarizing film is disposed on the phase retardation plate for absorbing the projective light, characterized in that:

the polarization degree of the light-polarizing film is between 15% and 93%, the corresponding permeability is between 46% and 80%, whereby the light-polarizing film with high permeability is utilizes to acquire necessary light-polarizing effect of emitting light of the color OLED itself, the color OLED doesn't need to increase power, and the color OLED can keep original economical lifetime. Furthermore, the incident external interference light is partly absorbed by the light-polarizing film; and the phase the incident external interference light is transformed by the phase retardation plate, the external interference light is reflected by the color OLED to be reflected light, the reflected light is transformed by the phase retardation plate again, and the reflected light is mostly absorbed by the light-polarizing film so as to improve the interference light.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of structure according to an embodiment of the present invention.

FIG. 2 is a schematic side view showing an optical route and a color organic light emitting diode provided with a light-polarizing film.

FIG. 3 is a schematic view of structure according to another embodiment of the present invention.

FIG. 4 is a schematic view of structure according to a further embodiment of the present invention.

FIG. 5 is a diagram showing the comparison between the permeability rate and polarization degree of different light-polarizing films.

FIG. 6 is a schematic diagram showing the remnant rate of external light of the OLED with the light-polarizing film.

FIG. 7 is a schematic diagram showing the distribution of the reflective rate of the light-polarizing film with an additional functional film.

FIG. 8 is a schematic diagram showing the distribution of the total reflective rate of a light-polarizing film with an additional bright film.

FIG. 9 is a schematic diagram showing the relation between the illumination and lifetime of the OLED.

### DESCRIPTION OF THE PREFERRED EMBODIMENTS

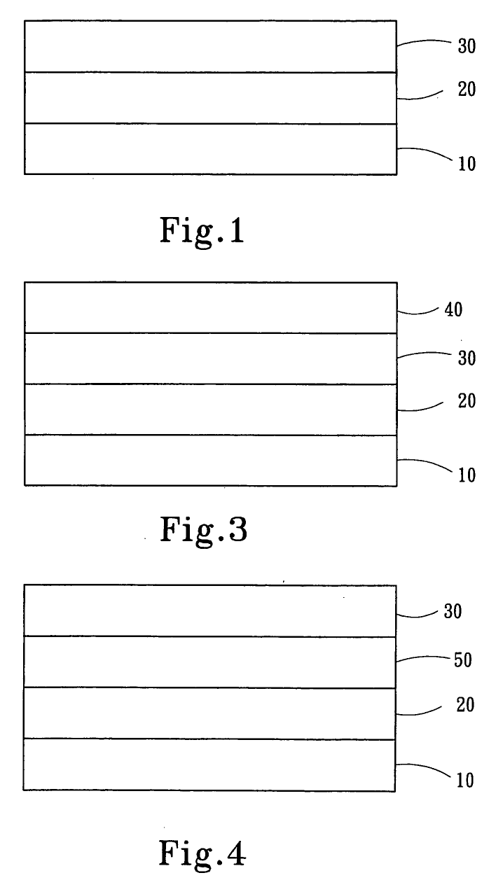

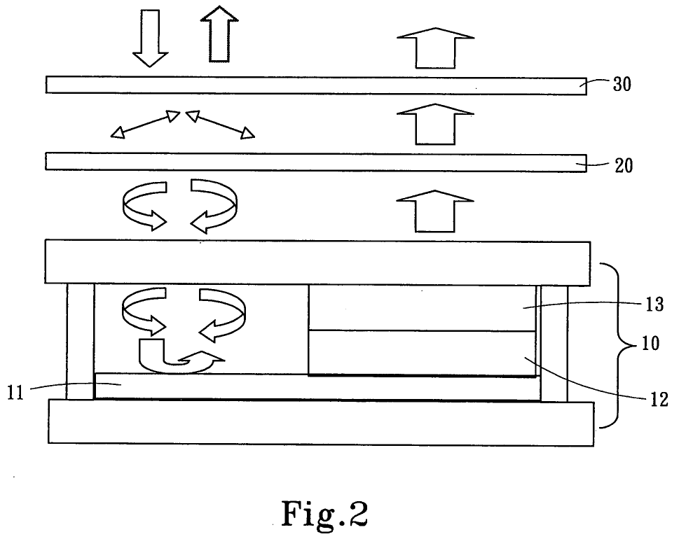

Referring to FIGS. 1 and 2, they are a schematic view of structure according to an embodiment of the present invention and a schematic side view showing an optical route. As shown in FIGS. 1 and 2, a phase retardation plate 20 is disposed on a color organic light emitting diode (OLED) 10 for transforming light phase, and a light-polarizing film 30 is disposed on the phase retardation plate 20 for absorbing the projective light. The OLED includes aluminum cathode layer 11, an emitting light (EL) layer 12 and an Indium Tin Oxide (ITO) layer 13. The light generated by the OLED itself can pass through the phase retardation plate 20 and the light-polarizing film 30 and then is displayed. However, an external light first passes through the light-polarizing film 30 with high permeability. The light-polarizing film 30 is constituted by a single-sided or two-sided attaching protective layer (triacetyl-cellulose, TAC) of a light-polarizing element (polyvinyl acetate, PVA). The light-polarizing film 30 is also constituted by laminar phase retardation plate. The polarization degree of the light-polarizing film 30 is between 15% and 93%, and the corresponding permeability is between 46% and 80%. The external light is absorbed and refracted by the light-polarizing film 30, and then the phase of the permeable part of the external light can be transformed by the phase retardation plate 20. The phase retardation plate 20 is constituted by ½ λ or ¼ λ of single layer or multi-layers stacked to one another. According to the best embodiment of the present invention, the polarization degree of the light-polarizing film 30 is between 70% and 80%, and the permeability of the light-polarizing film 30 is between 50% and 55%.

The present invention is a method for improving interference light of a color OLED. The phase retardation plate 20 is disposed on the color OLED 10 for transforming light phase, and then the light-polarizing film 30 is disposed on the phase retardation plate 20 for absorbing the projective light. The method for improving interference light of a color OLED includes the following steps of:

(A). absorbing a part of an external light by using the polarization degree of the light-polarizing film 30 being between 15% and 93%, and the corresponding being between 46% and 80% when the external light first passes through the light-polarizing film 30 and is processed in light vector distribution, and transforming incident angle of the other part of the external light by light-polarizing effect;

(B). transforming phase of the other part of the external light the first time by the phase retardation plate 20, then the other part of the external light into the color OLED 10 to generate reflection so as to form the interference light;

(C). transforming phase of the other part of the external light the second time by the phase retardation plate 20 after the interference light is reflected, then the interference light into the light-polarizing film 30; and

(D). absorbing a part of the interference light by using the light-polarizing film 30 after the interference light is processed in light vector distribution, and transforming incident angle of the other part of the interference light by light-polarizing effect, thereby decreasing the interference light reflected by the external light, decreasing the interference phenomenon of interlacing or overlapping between the emitting light of the OLED itself and the interference light, and then achieving the object of improving display quality.

Referring to FIG. 3, it is a schematic view of structure according to another embodiment of the present invention. As shown in FIG. 3, the present invention further includes an additional functional film 40, which is made by a manufacturing process of avoiding glisten, reflection and static electricity. The additional functional film 40 is disposed on the light-polarizing film 30. The reflected light of the OLED 10 with the additional functional film 40 is apparently decreased so as to achieve the object of avoiding glisten and reflection.

Referring to FIG. 4, it is a schematic view of structure according to a further embodiment of the present invention. As shown in FIG. 4, the present invention further includes an additional bright film 50, which is attached between the light-polarizing film 3 and the phase retardation plate 20. The additional bright film 50 increases the brightness of the panel of the OLED 10 so as to further increase the efficiency of light.

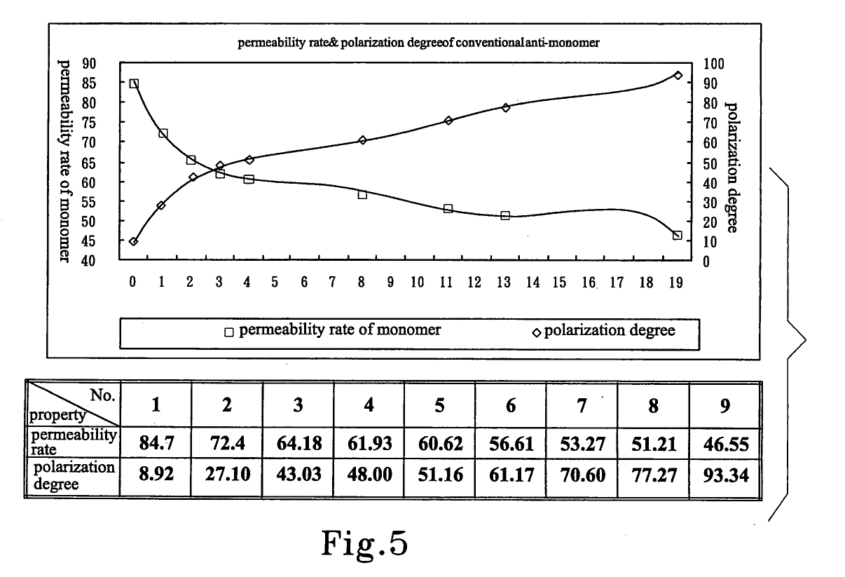

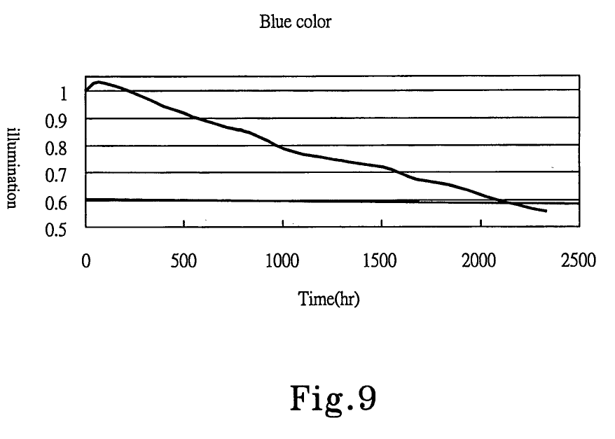

In order to describe the difference between the present invention and the prior art, Applicant provide the comparison between the present invention and the prior art, which is shown in FIGS. 5 to 9. Referring to FIG. 5, it is a diagram showing the comparison between the permeability rate and polarization degree of different light-polarizing films. The polarization degree is defined to be the light light-polarizing degree between the environmental incident light and the permeable light of the light-polarizing film. The OLED 10 is provided with No. 1-9 of different permeability of the light-polarizing film 30, and the relation between the permeability and polarization degree is shown in figure. The polarization degree is gradually decreased as the permeability is increased. In order to acquire high brightness and contrast, the permeability and polarization degree must be balanced. In the prior art, the permeability is set to about 30%, and the corresponding polarization degree is higher than 90%. Although the polarization degree is better, too low permeability cause the OLED 10 without enough illumination. Thus, the polarization degree is set to 70%-80%, and the corresponding permeability is 50%-55%. The range is located at No. 7 and 8 of the light-polarizing film 30.

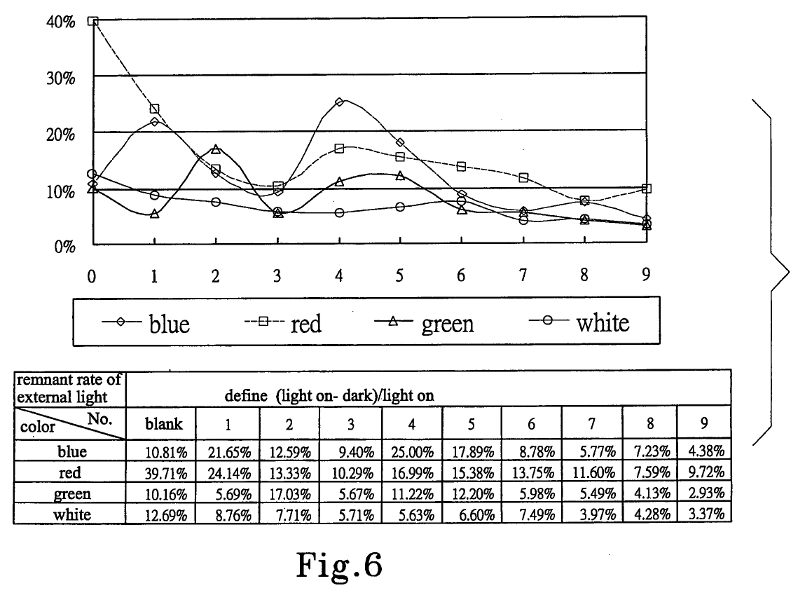

Referring to FIG. 6, it is a schematic diagram showing the remnant rate of external light of the OLED with the light-polarizing film. As shown in FIG. 6, four color light collocate the above-mentioned nine kinds of light-polarizing films 30, and the remnant rate of external light of the OLED is measured by Photo Research-PR-650, wherein No. 0 is the OLED without the light-polarizing film, No. 7 and 8 are the present invention. As shown in FIG. 6, the remnant rate of external light of No. 1 to 6 of the light-polarizing film is changed too much to be actually applied to the OLED 10. According to No. 9 of the light-polarizing film, the remnant rate of external light is slightly increased because the polarization degree is higher than others. The remnant rate of external light of the present invention (No. 7 and 8) is lower than that of the OLED without the light-polarizing film or the OLED collocating other light-polarizing film. Particularly, it is apparent to use a red light source because the wavelength (about 670 nm) of the red light is longer, the permeability is lower, and the reflective rate is higher than others. It is apparent to read an optical analysis diagram using the red light source, and therefore test data of most experiments use the red light source for an index. The test data shows most of the interference light is absorbed by the light-polarizing film 30.

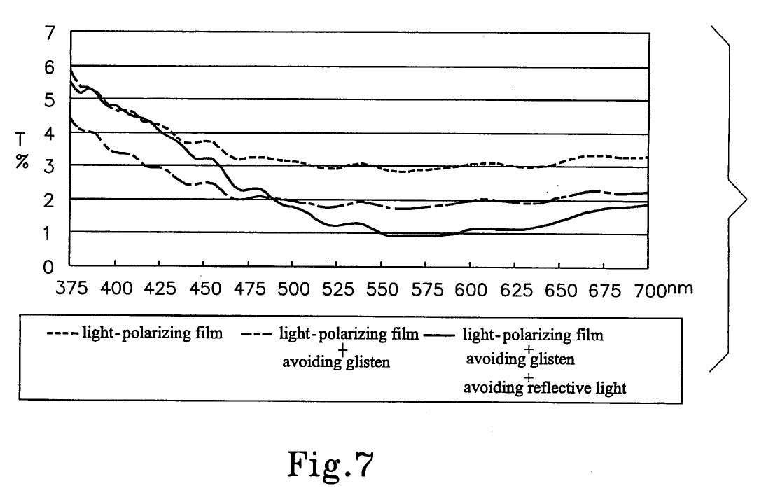

Referring to FIG. 7, it is a schematic diagram showing the distribution of the reflective rate of the light-polarizing film with an additional functional film. It is apparently seen that the reflective rate of the light-polarizing film 30 without an additional functional film is highest than others. If the light-polarizing film 30 is provided with an additional functional film 40 having a function of avoiding glisten, then it can effectively decrease the reflective rate. If the additional functional film 40 further having a function of avoiding reflection using avoiding reflection process, then it can further effectively decrease the reflective rate of each wavelength. Particularly, according to the wavelength range being between about 500 nm and 600 nm, the reflective rate much lower than that of the light-polarizing film 30 without an additional functional film. The wavelength range is just corresponding to the wavelength range (400-700 nm) of visible light of human eyes. Accordingly, the light-polarizing film 30 provided with the additional functional film 40 having functions of avoiding glisten and reflection can actually applied to the OLED, and the reflective rate of the light-polarizing film 30 can be effectively decreased.

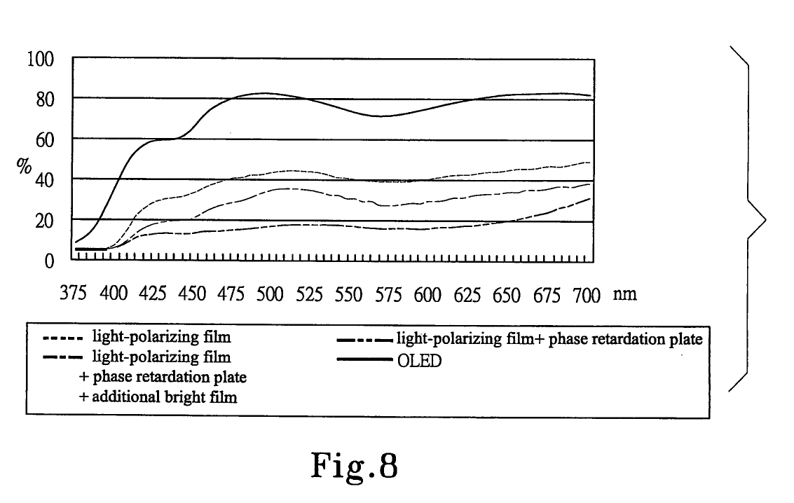

Referring to FIG. 8, it is a schematic diagram showing the distribution of the total reflective rate of a light-polarizing film with an additional bright film. The reflective rate of each wavelength of the OLED without a light-polarizing film, a phase retardation plate and an additional bright film is highest. If the OLED is provided with a light-polarizing film 30, then it can effectively decrease the reflective rate. If the OLED is further provided with a phase retardation plate 20 or an additional bright film 50, then the reflective rate of external light of the OLED with the phase retardation plate 20 or the additional bright film 50 is apparently lower than that the OLED without the phase retardation plate 20 or the additional bright film 50. Furthermore, the wavelength range is just corresponding to the wavelength range of visible light. Thus, the phase retardation plate 20 or the additional bright film 50 is provided for increasing the effective usage of light.

As described above, the present invention utilizes the light-polarizing film 30 to acquire necessary light-polarizing effect of emitting light of the color OLED itself, the present invention doesn't need to increase power, and the present invention can keep original economical lifetime. Furthermore, the incident external interference light is partly absorbed by the light-polarizing film 30, and the phase the incident external interference light is transformed by the phase retardation plate 20. Then, the external interference light is reflected by the OLED to be reflected light, the reflected light is transformed by the phase retardation plate 20 again, and the reflected light is mostly absorbed by the light-polarizing film 30 so as to improve the interference light. Moreover, the light-polarizing film of the present invention is provided with the additional functional film for acquiring functions of avoiding glisten and reflective light. According to the technical field of the invention, if the invention can solve the problem that technology and knowledge of one of ordinary skill in the art doesn't solve long time yet, then the invention should acquire non-obviousness. The permeability 46% to 80% chosen by the present invention is apparently different from the permeability 30% chosen by the prior art, therefore the invention should be a patentable invention.

Although the invention has been explained in relation to its preferred embodiment, it is not used to limit the invention. It is to be understood that many other possible modifications and variations can be made by those skilled in the art without departing from the spirit and scope of the invention as hereinafter claimed.

1. A light-polarizing film with high permeability for improving an, interference light of a color organic light emitting diode (OLED), wherein a phase retardation plate is disposed on the color OLED for transforming light phase, and the light-polarizing film is disposed on the phase retardation plate for absorbing the projective light, characterized in that:
the polarization degree of the light-polarizing film is between 15% and 93%, the corresponding permeability is between 46% and 80%, whereby the light-polarizing film with high permeability is utilizes to acquire necessary light-polarizing effect of emitting light of the color OLED itself, the color OLED doesn't need to increase power, and the color OLED can keep original economical lifetime. Furthermore, the incident external interference light is partly absorbed by the light-polarizing film; and the phase the incident external interference light is transformed by the phase retardation plate, the external interference light is reflected by the color OLED to be reflected light, the reflected light is transformed by the phase retardation plate again, and the reflected light is mostly absorbed by the light-polarizing film so as to improve the interference light.

2. The light-polarizing film with high permeability for improving an interference light of a color OLED according to claim 1, wherein the polarization degree of the light-polarizing film is between 70% and 80% according to the best embodiment of the present invention.

3. The light-polarizing film with high permeability for improving an interference light of a color OLED according to claim 1, wherein the permeability of the light-polarizing film is between 50% and 55% according to the best embodiment of the present invention.

4. The light-polarizing film with high permeability for improving an interference light of a color OLED according to claim 1, wherein the light-polarizing film is constituted by laminar phase retardation plate.

5. The light-polarizing film with high permeability for improving an interference light of a color OLED according to claim 1, wherein the light-polarizing film is constituted by a single-sided or two-sided attaching protective layer (triacetyl-cellulose, TAC) of a light-polarizing element (polyvinyl acetate, PVA).

6. The light-polarizing film with high permeability for improving an interference light of a color OLED according to claim 1, wherein the light-polarizing film is provided with an additional functional film formed by a manufacturing process of avoiding glisten, reflection and static electricity.

7. The light-polarizing film with high permeability for improving an interference light of a color OLED according to claim 1, wherein the light-polarizing film is provided with an additional bright film so as to increase the efficiency of light.

8. The light-polarizing film with high permeability for improving an interference light of a color OLED according to claim 1, wherein the phase retardation plate is constituted by ½ λ or ¼ λ of single layer or multi-layers stacked to one another.

9. A method for improving interference light of a color OLED, a phase retardation plate disposed on the color OLED for transforming light phase, and then the light-polarizing film disposed on the phase retardation plate for absorbing the projective light, the method for improving interference light of the color OLED comprising the following steps of:
(A). absorbing a part of an external light by using the polarization degree of the light-polarizing film being between 15% and 93%, and the corresponding being between 46% and 80% when the external light first passes through the light-polarizing film and is processed in light vector distribution, and transforming incident angle of the other part of the external light by light-polarizing effect;
(B). transforming phase of the other part of the external light the first time by the phase retardation plate, then the other part of the external light into the color OLED to generate reflection so as to form the interference light;
(C). transforming phase of the other part of the external light the second time by the phase retardation plate after the interference light is reflected, then the interference light into the light-polarizing film; and
(D). absorbing a part of the interference light by using the light-polarizing film after the interference light is processed in light vector distribution, and transforming incident angle of the other part of the interference light by light-polarizing effect, thereby decreasing the interference light reflected by the external light, decreasing the interference phenomenon of interlacing or overlapping between the emitting light of the OLED itself and the interference light, and then achieving the object of improving display quality.
